(19) United States
(12) Patent Application Publication
(10) Pub. No.: US 2025/0311484 A1
(43) Pub. Date: Oct. 2, 2025

(54) METHOD OF MANUFACTURING CERAMIC SUBSTRATE AND METHOD OF MANUFACTURING LIGHT-EMITTING DEVICE

(71) Applicant: NICHIA CORPORATION, Anan-shi (JP)

(72) Inventor: Takashi KAWAMATA, Tokushima-shi (JP)

(73) Assignee: NICHIA CORPORATION, Anan-shi (JP)

(21) Appl. No.: 19/091,822

(22) Filed: Mar. 27, 2025

(30) Foreign Application Priority Data
Mar. 29, 2024 (JP) 2024-057598

(51) Int. Cl. H10H 20/01; H10H 20/858

(52) U.S. Cl. CPC H10H 20/0365; H10H 20/8581

(57) ABSTRACT

A method of manufacturing a ceramic substrate includes forming a through hole or a recess in a ceramic plate containing aluminum nitride by irradiating the ceramic plate with a laser such that aluminum is precipitated. The ceramic plate has a first surface and a second surface opposite to the first surface. The method also includes disposing an electrically-conductive paste within the through hole or the recess, and forming an electrically-conductive member by sintering the electrically-conductive paste at a temperature in a range of 450° C. or more and 720° C. or less.

### CROSS-REFERENCE TO RELATED APPLICATIONS

The present application claims priority under 35 U.S.C. § 119 to Japanese Patent Application No. 2024-057598, filed Mar. 29, 2024, the content of which is hereby incorporated by reference in its entirety.

### BACKGROUND

### 1. Technical Field

The present disclosure relates to a method of manufacturing a ceramic substrate and a method of manufacturing a light-emitting device.

### 2. Description of Related Art

In recent years, in order to achieve miniaturization, high functionality, and integration of electronic devices or components, an insulating substrate has been proposed, in which a through hole (also referred to as a “hole”, a “via”, or the like) is formed in the insulating substrate and an electrically-conductive material is disposed within the through hole so as to electrically conduct both surfaces of the substrate to each other. For example, a method of manufacturing a printed circuit board is known. The method of manufacturing a printed circuit board includes: irradiating an insulating substrate made of aluminum nitride and formed in a flat plate shape with a laser beam so as to form a via hole at a predetermined position and precipitate an aluminum precipitated film on an inner wall of the via hole; applying zinc plating to the surface of the aluminum precipitated film and subsequently heating the aluminum precipitated film in an oxidizing atmosphere so as to form a zinc oxide film on the inner wall of the via hole; disposing a connection via by filling the inside of the zinc oxide film with a metal having good conductivity; and printing a predetermined conductor pattern on both a front surface and a back surface (see Japanese Patent Publication No. H3-46298, for example).

### SUMMARY

Embodiments of the present disclosure can provide a method of manufacturing a ceramic substrate and a method of manufacturing a light-emitting device, in which high durability and good heat dissipation are obtained and the adhesion between a ceramic plate and an electrically-conductive member within a through hole or a recess of the ceramic plate can be improved.

A method of manufacturing a ceramic substrate according to one embodiment of the present disclosure includes: forming a through hole or a recess in a ceramic plate containing aluminum nitride and having a first surface and a second surface opposite to the first surface, by irradiating the ceramic plate with a laser such that aluminum is precipitated; disposing an electrically-conductive paste within the through hole or the recess; and forming an electrically-conductive member by sintering the electrically-conductive paste at 450° C. or more and 720° C. or less.

A method of manufacturing a light-emitting device according to one embodiment of the present disclosure includes: preparing the ceramic substrate manufactured by the method of manufacturing the ceramic substrate according to one embodiment; and disposing a light-emitting element including an electrode over the ceramic substrate, wherein the electrode and the electrically-conductive member are electrically connected to each other.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic top view illustrating an example of a ceramic substrate according to a first embodiment.

FIG. 1B is a schematic bottom view illustrating an example of the ceramic substrate according to the first embodiment.

FIG. 1C is a schematic cross-sectional view illustrating a cross section taken along line IC-IC of FIG. 1A and FIG. 1B.

FIG. 2 is a schematic cross-sectional view illustrating a ceramic substrate according to a modification of the first embodiment.

FIG. 3A is a schematic top view illustrating an example of a ceramic substrate according to a second embodiment.

FIG. 3B is a schematic bottom view illustrating an example of the ceramic substrate according to the second embodiment.

FIG. 3C is a schematic cross-sectional view illustrating a cross section taken along line IIIC-IIIC of FIG. 3A and FIG. 3B.

FIG. 4 is a schematic cross-sectional view illustrating a ceramic substrate according to a modification of the second embodiment.

FIG. 5 is a flowchart illustrating an example of a method of manufacturing the ceramic substrate according to the first embodiment.

FIG. 6A is a schematic cross-sectional view illustrating a ceramic plate used in the method of manufacturing the ceramic substrate according to the first embodiment.

FIG. 6B is a schematic cross-sectional view illustrating an example of forming a through hole in the method of manufacturing the ceramic substrate according to the first embodiment.

FIG. 6C is a schematic cross-sectional view illustrating an example of disposing an electrically-conductive paste in the method of manufacturing the ceramic substrate according to the first embodiment.

FIG. 6D is a schematic cross-sectional view illustrating an example of forming an electrically-conductive member in the method of manufacturing the ceramic substrate according to the first embodiment.

FIG. 6E is a schematic cross-sectional view illustrating an example of polishing or grinding the electrically-conductive member in the method of manufacturing the ceramic substrate according to the first embodiment.

FIG. 7 is a schematic cross-sectional view illustrating an example of a light-emitting device according to an embodiment.

FIG. 8A is a perspective view illustrating an application example of light-emitting devices according to an embodiment.

FIG. 8B is a cross-sectional view illustrating a cross section taken along line VIIIB-VIIIB of FIG. 8A.

FIG. 9 is a flowchart illustrating an example of a method of manufacturing a light-emitting device according to an embodiment.

FIG. 10 is a cross-sectional observation image of a through hole after laser irradiation in forming the through hole in Example 1.

### DETAILED DESCRIPTION

A ceramic substrate, a method of manufacturing the ceramic substrate, a light-emitting device, and a method of manufacturing the light-emitting device according to embodiments of the present disclosure will be described in detail with reference to the accompanying drawings. The embodiments described below illustrate the ceramic substrate, the method of manufacturing the ceramic substrate, the light-emitting device, and the method of manufacturing the light-emitting device that embody technical ideas underlying the present invention, but the present invention is not limited to the described embodiments.

In addition, unless otherwise specified, the dimensions, materials, shapes, relative arrangements, and the like of components described in the embodiments are not intended to limit the scope of the present disclosure thereto, but are described as examples. The sizes, positional relationships, and the like, of members illustrated in the drawings may be exaggerated for a better understanding of the structures. Further, in the following description, the same names and reference numerals refer to the same or similar members, and a detailed description thereof will be omitted as appropriate. To avoid excessive complication of the drawings, a schematic view in which some elements are not illustrated may be used, or an end view illustrating only a cleaved surface may be used as a cross-sectional view.

Further, in the present disclosure, polygonal shapes, such as rectangular shapes, triangular shapes, and quadrangular shapes, including polygonal shapes with rounded corners, beveled corners, angled corners, reverse-rounded corners are also referred to as polygonal shapes. Further, not only shapes with such modification at corners (ends of sides) but also shapes with modifications at intermediate portions of sides of the shapes are also referred to as polygonal shapes. That is, shapes that are based on polygonal shapes and partially modified are also interpreted as “polygonal shapes” in the present disclosure.

The same applies not only to polygonal shapes but also to terms representing specific shapes such as trapezoidal shapes, circular shapes, projections, and recesses. The same also applies when referring to sides forming such a shape. That is, even when a corner or an intermediate portion of a certain side is modified, the “side” is construed as including the modified portion. When a “polygonal shape” or a “side” without partial modification is to be distinguished from a modified shape, “strict” will be added to the description as in, for example, a “strict quadrangular shape”.

Further, in the following description, terms indicating specific directions and positions (for example, “upper”, “upward”, “lower”, “downward”, “X”, “Y”, “Z”, and other terms including these terms) are used as necessary. These terms are used to facilitate understanding of the present invention with reference to the drawings, and the technical scope of the present invention is not unduly limited by the meaning of these terms. For example, the term “upper surface” does not necessarily mean that the “upper surface” must face upward at all times. The same reference numerals appearing in a plurality of drawings refer to the same or similar portions or members. Further, in the embodiment, “covering” is not limited to a case of directly covering a member, but also includes a case of indirectly covering a member, for example, via another member.

Further, in the present specification and the claims, if there are multiple components and these components are to be distinguished from one another, the components may be distinguished by adding terms “first”, “second”, and the like before the names of the components.

### Ceramic Substrate

### First Embodiment

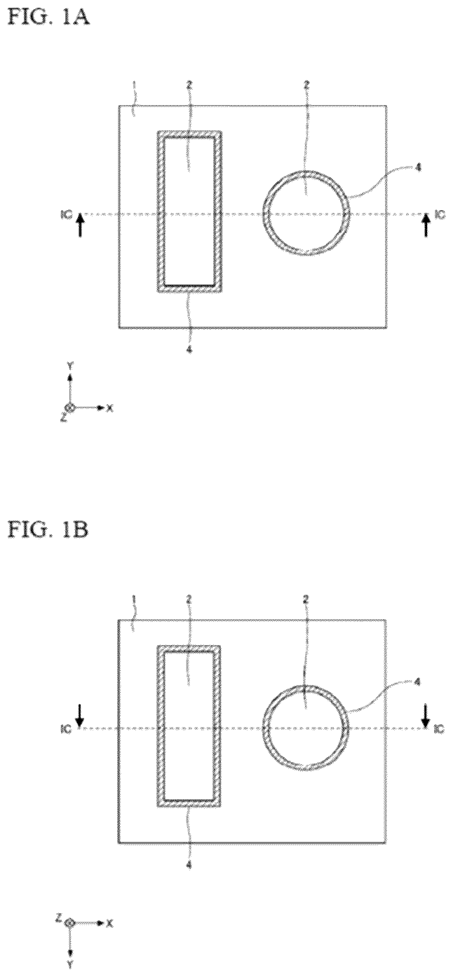

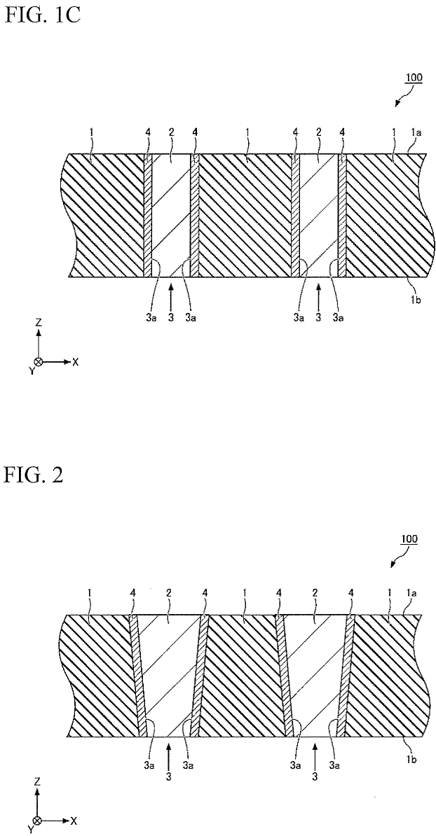

FIG. 1A is a schematic top view illustrating an example of a ceramic substrate according to a first embodiment. FIG. 1B is a schematic bottom view illustrating an example of the ceramic substrate according to the first embodiment. FIG. 1C is a schematic cross-sectional view illustrating a cross section taken along line IC-IC of FIG. 1A and FIG. 1B. Each component of the ceramic substrate 100 will be described below.

A ceramic substrate 100 according to the first embodiment includes a ceramic plate 1 containing aluminum nitride and having a first surface 1a, a second surface 1b opposite to the first surface 1a, and a through hole 3 connecting the first surface 1a and the second surface 1b; a continuous aluminum layer 4; and an electrically-conductive member 2 formed within the through hole 3. An inner surface 3a defining the through hole 3 has irregularities, and the continuous aluminum layer 4 is disposed so as to enter the irregularities. However, the continuous aluminum layer 4 disposed on the inner surface 3a defining the through hole 3 and the electrically-conductive member 2 formed within the through hole 3 are not arranged such that the continuous aluminum layer 4 is formed in a tubular shape and a clear interface is formed between the continuous aluminum layer 4 and the electrically-conductive member 2. That is, the aluminum layer 4 is continuously disposed on the inner surface 3a defining the through hole 3, but at least a portion of the electrically-conductive member 2 formed within the through hole 3 is melted, and the electrically-conductive member 2 and the aluminum layer 4 are partially mixed with each other without a clear interface between the electrically-conductive member 2 and the aluminum layer 4. As will be described later, both the aluminum layer 4 and the electrically-conductive member 2 are once melted and solidified during a manufacturing process, and thus a clear interface is not formed or is less likely to be formed.

### Ceramic Plate 1

The ceramic plate 1 is an insulating member serving as a base in which the electrically-conductive member 2 is formed. The ceramic plate 1 is sintered, and it is preferable that the ceramic plate 1 is not in a softened state before being sintered.

The ceramic plate 1 contains aluminum nitride. The ceramic plate 1 preferably contains aluminum nitride as a main material, and can further contain other auxiliary materials as necessary. As used herein, the term “main material” means a material having the largest amount among materials constituting the ceramic plate 1.

The auxiliary materials of the ceramic plate 1 are not particularly limited, and examples of the auxiliary materials include a ceramic, other than aluminum nitride, and glass. One of these materials can be used alone or two or more of these materials can be used in combination.

The ceramic other than aluminum nitride is not particularly limited, and examples of the ceramic other than aluminum nitride include nitride-based ceramics such as silicon nitride and boron nitride; oxide-based ceramics such as aluminum oxide, silicon oxide, calcium oxide, and magnesium oxide; silicon carbide; mullite; and borosilicate glass. One of these materials can be used alone or two or more of these materials can be used in combination.

The ceramic plate 1 is preferably a plate-shaped member having a rectangular outer shape in a plan view. The rectangular shape can be a rectangular shape having long sides and short sides. The rectangular shape can include a square shape unless specifically described as excluding a square shape. The outer shape of the ceramic plate 1 in a plan view is not limited to a rectangular shape, and can be a circular shape, an elliptical shape, a polygonal shape, or the like.

The first surface 1a is preferably a flat surface, but is not necessarily a flat surface. The first surface 1a is preferably flat because, when the ceramic substrate 100 is used in a light-emitting device, the light-emitting element can be suitably disposed.

The second surface 1b is a surface of the ceramic plate 1 opposite to the first surface 1a. The second surface 1b is preferably a flat surface, but is not necessarily a flat surface. The second surface 1b is preferably flat because, when the ceramic substrate 100 is used in a light-emitting device, the ceramic substrate 100 can be suitably disposed on a mounting substrate

In the ceramic substrate 100 according to the first embodiment, a surface of the ceramic plate 1 on the upper side of FIG. 1C is illustrated as the first surface 1a, and a surface of the ceramic plate 1 on the lower side is of FIG. 1C is illustrated as the second surface 1b; however, this is for convenience of illustration, and when the ceramic substrate 100 is used in a light-emitting device, a mounting substrate can be disposed on the first surface 1a and a light-emitting element can be disposed on the second surface 1b.

The first surface 1a and the second surface 1b are parallel to each other, for example. As used herein, the term “parallel” with respect to the surfaces of the ceramic plate 1 allows a tolerance within ±5 degrees.

The through hole 3 connects the first surface 1a and the second surface 1b. The through hole 3 is, for example, a via hole.

The shape of an opening of the through hole 3 of the ceramic plate 1 in a plan view is preferably a circular shape, but can be an elliptical shape. The shape of the opening of the through hole 3 of the ceramic plate 1 in a plan view is not limited to a circular shape or an elliptical shape, and can be a polygonal shape including a rectangular shape.

In the ceramic substrate 100 according to the first embodiment, the opening diameter of an opening of the through hole 3 formed in the first surface 1a and the opening diameter of an opening of the through hole 3 formed in the second surface 1b of the ceramic plate 1 in a plan view are not particularly limited, and can be appropriately selected according to the purpose. The opening diameter of the opening of the through hole 3 formed in the first surface 1a and the opening diameter of the opening of the through hole 3 formed in the second surface 1b are preferably 40 μm or more and 500 μm or less, and more preferably 50 μm or more and 200 μm or less.

In the ceramic substrate 100 according to the first embodiment, the opening diameter of the opening of the through hole 3 formed in the first surface 1a of the ceramic plate 1 is the same as the opening diameter of the opening of the through hole 3 formed in the second surface 1b of the ceramic plate 1. As used herein, the term “same” with respect to the opening diameters of the through hole 3 of the ceramic plate 1 allows a tolerance within ±5%.

In a case where the shape of an opening of the through hole 3 is a circular shape or an elliptical shape, the “opening diameter” is the maximum diameter of the opening. In a case where the shape of the opening of the through-hole 3 of the ceramic plate 1 is a rectangular shape in a plan view, the “opening diameter” is the length of a diagonal line of the opening.

The number of through holes 3 in the ceramic plate 1 is not particularly limited, and can be one or more. It is preferable that the number of through holes 3 is more than one from the viewpoint of mounting a light-emitting device on the ceramic substrate.

In a case where the ceramic plate 1 has a plurality of through holes 3, the arrangement of the plurality of through holes 3 in a plan view of the ceramic plate 1, a pitch between one through hole 3 and another through hole 3 adjacent to each other, and the like are not particularly limited, and can be appropriately selected according to the purpose.

The continuous aluminum layer 4 is disposed on the inner surface 3a defining the through hole 3. That is, the aluminum layer 4 is disposed at the interface between the inner surface 3a defining the through hole 3 and the electrically-conductive member 2. The aluminum layer 4 improves the adhesion between the ceramic plate 1 and the electrically-conductive member 2 formed within the through hole 3.

The inner surface 3a defining the through hole 3 of the ceramic plate 1 has irregularities and is roughened. A recessed portion of the inner surface 3a defining the through hole 3 has an irregular microstructure. In the present disclosure, the irregular microstructure of the recessed portion of the inner surface 3a defining the through hole 3 can be referred to as, for example, a root shape or a tree shape. Aluminum is present in the recessed portion having a root shape. Therefore, the aluminum layer 4 contains aluminum present on the inner surface 3a defining the through hole 3, and contains aluminum present in the inner surface 3a. More specifically, the aluminum layer 4 can contain a material of the ceramic plate 1 and aluminum, and can further contain a component derived from the electrically-conductive member 2.

The aluminum layer 4 being “continuously” disposed means that that aluminum is present in the recessed portion having a root shape of the inner surface 3a defining the through hole 3, and the aluminum layer 4 is disposed on the inner surface 3a defining the through hole 3 without being interrupted. The aluminum layer 4 is disposed on substantially the entire surface of the through hole 3 from the first surface 1a side to the second surface 1b side. Depending on the processing state, there is a possibility that the aluminum layer 4 is not disposed on a portion on the first surface 1a side of the through hole 3 or a portion on the second surface 1b side of the through hole 3. However, the aluminum layer 4 is disposed on 80% or more, preferably 90% or more, and more preferably 95% or more of the inner surface 3a defining the through hole 3.

The arithmetic average roughness Ra of the inner surface 3a defining the through hole 3 is not particularly limited, and can be appropriately selected according to the purpose. It is preferable that the arithmetic average roughness Ra of the inner surface 3a defining the through hole 3 is 1.0 μm or more and 3.5 μm or less. The arithmetic average roughness Ra of the inner surface 3a defining the through hole 3 is measured in accordance with JIS B 0601 by using a stylus-type surface roughness meter (for example, SE3500 manufactured by Kosaka Laboratory Ltd.) provided with a diamond stylus having a tip with a curvature radius r of 2 μm.

The average thickness of the aluminum layer 4 is not particularly limited, and is preferably 10 μm or more and 35 μm or less, and more preferably 10 μm or more and 25 μm or less.

In the ceramic substrate 100 according to the first embodiment, the average thickness of the aluminum layer 4 is a value measured as follows. A scanning electron microscopy (SEM) image is obtained by observing, at a magnification of 250 times, at least a portion of the electrically-conductive member 2 and a region X extending at least 50 μm in the depth direction of the recessed portion from the inner surface 3a defining the through hole 3 of the ceramic plate 1 in a cross section taken along the thickness direction of the ceramic substrate 100 and passing through the centroid of the through hole 3. In the SEM image of the region X, a maximum length 1 of the root-shaped recessed portion extending from the inner surface 3a defining the through hole 3 toward the ceramic plate 1 is measured. Similarly, a maximum length 1 is measured at any five points selected from the ceramic substrate 100, and an average maximum length L of the five points is obtained. The average maximum length L is defined as the average thickness of the aluminum layer 4 of the ceramic substrate 100 according to the first embodiment.

### Electrically-Conductive Member 2

The electrically-conductive member 2 is a member serving as electrical wiring in the ceramic substrate 100. The electrically-conductive member 2 is, for example, a via. In the ceramic substrate 100 according to the first embodiment, the electrically-conductive member 2 is formed within the through hole 3. The surface on the first surface 1a side of the electrically-conductive member 2 is preferably formed so as to be coplanar with the first surface 1a of the ceramic plate 1, and the surface on the second surface 1b side of the electrically-conductive member 2 is preferably formed so as to be coplanar with the second surface 1b of the ceramic plate 1.

The electrically-conductive member 2 preferably contains aluminum.

The ceramic substrate 100 according to the first embodiment can be suitably manufactured by a method of manufacturing the ceramic substrate according to the first embodiment, which will be described later.

### Modification of First Embodiment

FIG. 2 is a schematic cross-sectional view illustrating a ceramic substrate according to a modification of the first embodiment.

A ceramic substrate 100 according to the modification differs from the ceramic substrate 100 according to the first embodiment in that the opening diameter of the through hole 3 in the first surface 1a of the ceramic plate 1 is larger than the opening diameter of the through hole 3 in the second surface 1b of the ceramic plate 1. If the opening diameter of the through hole 3 of the ceramic plate 1 is described as “large”, it means that the opening diameter of the through hole 3 in the second surface 1b is larger than the opening diameter of the through hole 3 in the first surface 1a of the ceramic plate 1 by more than 5%.

In FIG. 2, an example in which the opening diameter of the through hole 3 in the first surface 1a of the ceramic plate 1 is larger than the opening diameter of the through hole 3 in the second surface 1b of the ceramic plate 1 is illustrated. However, the first surface 1a and the second surface 1b are merely illustrated in order to distinguish between the surfaces in the drawing for reasons of expediency, and the opening diameter of the through hole 3 in the second surface 1b of the ceramic plate 1 can be larger than the opening diameter of the through hole 3 in the first surface 1a of the ceramic plate 1.

The ratio of the opening diameter of the through hole 3 in the first surface 1a to the opening diameter of the through hole 3 in the second surface 1b is not particularly limited.

### Second Embodiment

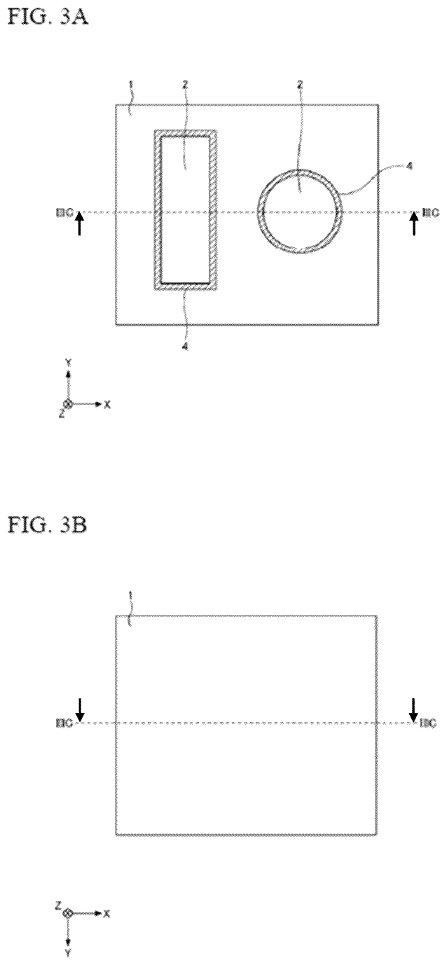

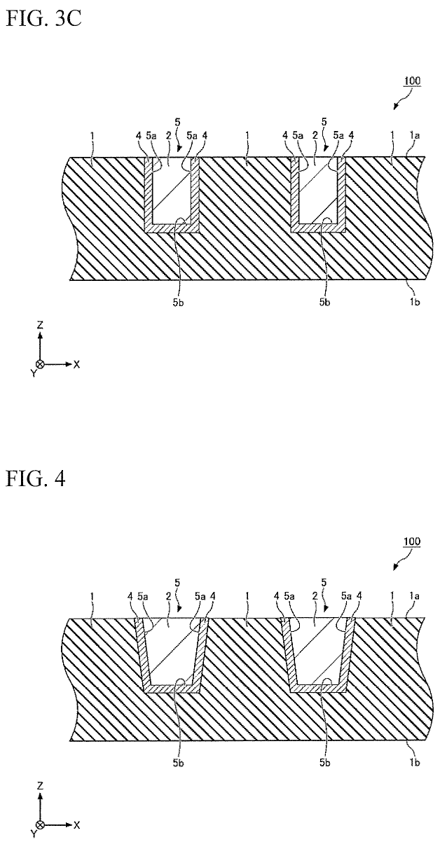

FIG. 3A is a schematic top view illustrating an example of a ceramic substrate according to a second embodiment. FIG. 3B is a schematic bottom view illustrating an example of the ceramic substrate according to the second embodiment. FIG. 3C is a schematic cross-sectional view illustrating a cross section taken along line IIIC-IIIC of FIG. 3A and FIG. 3B.

A ceramic substrate 100 according to the second embodiment includes a ceramic plate 1 containing aluminum nitride and having a first surface 1a, a second surface 1b opposite to the first surface 1a, and a recess 5 in at least one of the first surface 1a or the second surface 1b; a continuous aluminum layer 4; and an electrically-conductive member 2 formed within the recess 5. An inner surface defining the recess 5 has irregularities, and the continuous aluminum layer 4 is disposed so as to enter the irregularities.

FIG. 3A illustrates an example in which the first surface 1a has the recess 5. However, the first surface 1a and the second surface 1b are merely illustrated in order to distinguish between the surfaces in the drawing for reasons of expediency, and the second surface 1b can have the recess 5.

The ceramic substrate 100 according to the second embodiment differs from the ceramic substrate 100 according to the first embodiment in that the through hole 3 in the ceramic substrate 100 according to the first embodiment is replaced with the recess 5. Configurations other than the recess 5 are the same as those of the ceramic substrate 100 according to the first embodiment.

The recess 5 is a hole with a bottom, that does not penetrate from the first surface 1a to the second surface 1b. The recess 5 has a lateral surface 5a and a bottom 5b. The lateral surface 5a connects an opening and the bottom 5b in the Z-axis direction. That is, an inner surface defining the recess 5 consists of the lateral surface 5a and the bottom 5b of the recess 5. The recess 5 has the same configuration as that of the through hole 3 except that the shape of the recess 5 in a cross-sectional view in the Z-axis direction is different from the shape of through hole 3.

The maximum depth of the recess 5, that is, the maximum length of the inner surface defining the recess 5 in the Z-axis direction in a cross-sectional view, is not particularly limited, and can be appropriately selected according to the thickness of the ceramic plate 1. The maximum depth of the recess 5 is preferably 25 μm or more and 300 μm or less, more preferably 50 μm or more and 200 μm or less, and even more preferably 50 μm or more and 100 μm or less.

### Modification of Second Embodiment

FIG. 4 is a schematic cross-sectional view illustrating a ceramic substrate according to a modification of the second embodiment.

A ceramic substrate 100 according to the modification of the second embodiment differs from the ceramic substrate 100 according to the first embodiment in that the opening diameter of a recess 5 is larger than the diameter of a bottom 5b of the recess 5. If the opening diameter of the recess 5 of the ceramic plate 1 is described as “large”, it means that the diameter of the bottom 5b of the recess 5 is larger than the opening diameter of the recess 5 by more than 5%.

The ratio of the opening diameter of the recess 5 to the diameter of the bottom 5b of the recess 5 is not particularly limited.

According to the second embodiment, the shape of the recess 5 of the ceramic substrate 100 in a cross-sectional view in the Z-axis direction is not limited to a rectangular shape, and can be, for example, a triangular shape, a trapezoidal shape, a U-shape, or the like.

### Method of Manufacturing Ceramic Substrate

### First Embodiment

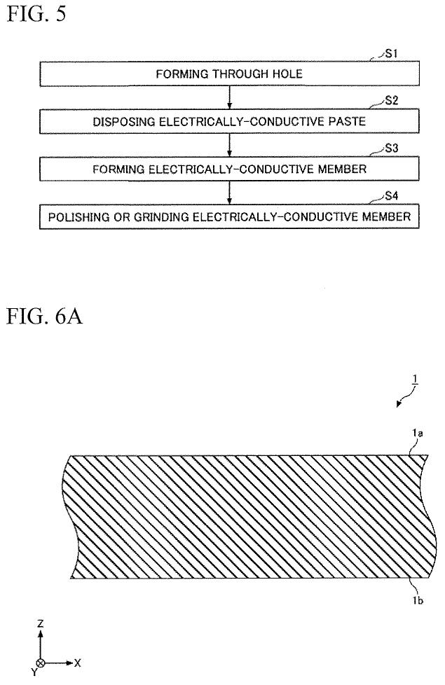

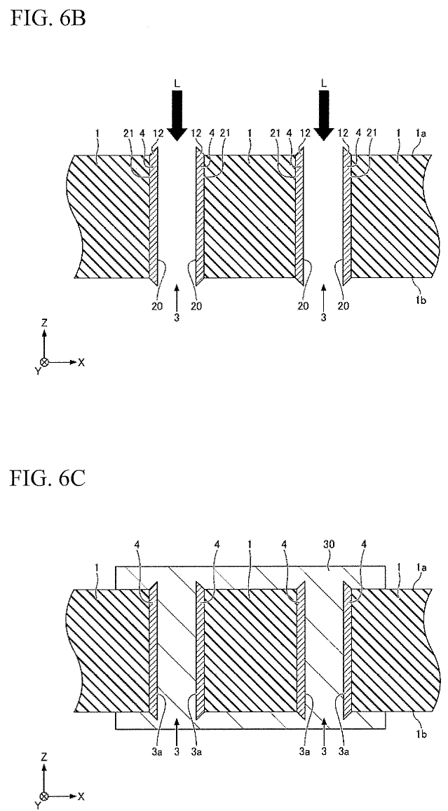

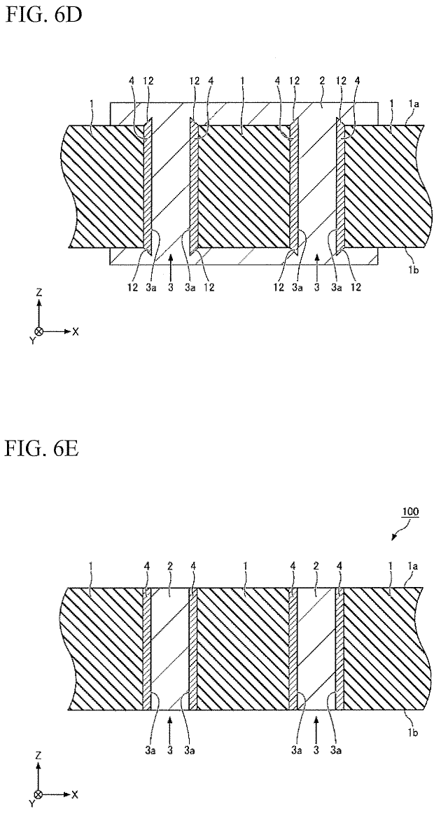

FIG. 5 is a flowchart illustrating an example of a method of manufacturing the ceramic substrate according to the first embodiment. The method of manufacturing the ceramic substrate according to the first embodiment will be described with reference to FIG. 6A to FIG. 6E.

The method of manufacturing the ceramic substrate according to the first embodiment includes: S1 of forming a through hole 3 in a ceramic plate 1 containing aluminum nitride and having a first surface 1a and a second surface 1b opposite to the first surface 1a by irradiating the ceramic plate 1 with a laser L such that an aluminum layer 4 is precipitated; S2 of disposing an electrically-conductive paste 30 within the through hole 3; and S3 forming an electrically-conductive member 2 by sintering the electrically-conductive paste 30 at 450° C. or more and 720° C. or less. It is preferable that the method of manufacturing the ceramic substrate according to the first embodiment further includes S4 of polishing or grinding the electrically-conductive member 2.

### (S1) Forming Through Hole

FIG. 6A is a schematic cross-sectional view illustrating an example of the ceramic plate used in the method of manufacturing the ceramic substrate according to the first embodiment. FIG. 6B is a schematic cross-sectional view illustrating an example of forming the through hole in the method of manufacturing the ceramic substrate according to the first embodiment.

The ceramic plate 1 containing aluminum nitride and having the first surface la and the second surface 1b opposite to the first surface 1a is prepared. The ceramic plate 1 can be a ceramic precursor before being sintered or can be a sintered ceramic; however, a sintered ceramic is preferable because the sintered ceramic has no dimensional change due to sintering.

In S1 of forming the through hole, the through hole 3 is formed in the ceramic plate 1 by irradiating the ceramic plate 1 with the laser L such that the aluminum layer 4 is precipitated. The laser L is not particularly limited as long as the aluminum layer 4 derived from the ceramic plate 1 can be precipitated in an irradiation region 20 of the through hole 3. However, the laser L that can be used for thermal processing is preferable. The aluminum layer 4 is continuously formed on an inner surface 3a defining the through hole 3. At this time, aluminum nitride in the vicinity of the inner surface 3a defining the through hole 3 of the ceramic plate 1 has irregularities, and the aluminum layer 4 enters the irregularities. This is because, when the through hole 3 is formed, a rapid temperature rise occurs in aluminum nitride due to laser irradiation, a phase change in which a portion of aluminum nitride is melted and sublimated occurs, and ablation occurs. Therefore, a physical processing method such as drilling is not used to form a through hole having irregularities in the ceramic plate 1 and no molten aluminum is poured into the irregularities to form an inner surface of the through hole.

In the method of manufacturing the ceramic substrate according to the first embodiment, a continuous wave (CW) is obtained by maximizing the pulse width of the laser L in a pulse repetition period, and the pulse width of the laser L includes a continuous wave.

The laser L that can be used for thermal processing preferably has a pulse width in a microsecond region or a nanosecond region, more preferably in the nanosecond region, and even more preferably in a range from 1 nanosecond to 23 nanoseconds.

Examples of the laser L that can be used for thermal processing include a laser having an oscillation wavelength of 750 nm or more, a laser having an output of 500 W or more, and the like. Specific examples of the laser L that can be used for thermal processing include a fiber laser, a disk laser, a CO₂ laser, and the like.

The pulse width, the output, and the wavelength of the laser L that can be used for thermal processing are not particularly limited. For example, thermal processing can be performed under conditions of a fiber laser (CW: 1 nanosecond, wavelength: 532 nm, output: 1,500 W), a disk laser (CW: 3 nanoseconds, wavelength: 1,064 nm, output: 1,000 W), or a CO₂ laser (pulse: 16 nanoseconds x 200 times, wavelength: 10,600 nm, output conversion: 300 W to 700 W). However, the conditions are not limited thereto as long as the aluminum layer 4 is precipitated.

A predetermined region of the first surface 1a of the ceramic plate 1 is irradiated with the laser L in the Z-axis direction and thermally processed so as to remove ceramic mainly by melting and sublimating the irradiation region 20 where the laser L is absorbed, and as a result the through hole 3 penetrating from the first surface 1a to the second surface 1b is formed. At this time, the aluminum layer 4 is precipitated in the irradiation region 20 of the ceramic plate 1 irradiated with the laser L. The through hole 3 can be formed by irradiating the predetermined region with the laser L once, or can be formed by irradiating the predetermined region with the laser L multiple times to gradually remove the ceramic.

In the ceramic plate 1 irradiated with the laser L, heat generated by the irradiation with the laser L spreads not only to the irradiation region 20 irradiated with the laser L but also to a peripheral region 21 from the irradiation region 20. Therefore, in the ceramic plate 1, the aluminum layer 4 is precipitated not only in the irradiation region 20 irradiated with the laser L, but also in the peripheral region 21 located inside the ceramic plate 1 in the X-axis direction from the irradiation region 20.

### (S2) Disposing Electrically-Conductive Paste

FIG. 6C is a schematic cross-sectional view illustrating an example of disposing the electrically-conductive paste in the method of manufacturing the ceramic substrate according to the first embodiment.

In S2 of disposing the electrically-conductive paste, the electrically-conductive paste 30 can be disposed within the through hole 3 by filling the through hole 3 with the electrically-conductive paste 30. In S2 of disposing the electrically-conductive paste, the electrically-conductive paste 30 is preferably disposed such that the electrically-conductive paste 30 contacts the inner surface 3a defining the through hole 3.

In S2 of disposing the electrically-conductive paste, the electrically-conductive paste 30 can be disposed by using, for example, screen-printing, metal mask printing, or injection using a nozzle to fill the through hole 3 with the electrically-conductive paste 30, such that the surfaces of the electrically-conductive paste 30 have substantially the same height as the first surface 1a and the second surface 1b of the ceramic plate 1, respectively.

In S2 of disposing the electrically-conductive paste, in addition to filling the through hole 3 with the electrically-conductive paste 30, the electrically-conductive paste 30 is preferably disposed so as to cover the openings of the through hole 3 and at least a portion of at least one of the first surface 1a or the second surface 1b of the ceramic plate 1. This can prevent a decrease in dimensional accuracy due to volumetric shrinkage when the electrically-conductive paste 30 is sintered in S3 of forming the electrically-conductive member.

As a specific example, when the through hole 3 is filled with the electrically-conductive paste 30 in S2 of disposing the electrically-conductive paste, the through hole 3 is filled with the electrically-conductive paste 30 from the first surface 1a of the ceramic plate 1 by using a squeeze, which is a tool used for screen printing, and further, the through hole 3 is filled with the electrically-conductive paste 30 from the second surface 1b of the ceramic plate 1 by using the squeeze as in the case of the first surface 1a. In this manner, the electrically-conductive paste 30 can be disposed so as to cover the openings of the through hole 3 and at least a portion of at least one of the first surface 1a and the second surface 1b of the ceramic plate 1. That is, the electrically-conductive paste 30 can be disposed so as to cover at least a portion of at least one of the first surface 1a or the second surface 1b of the ceramic plate 1 continuously from the through hole 3.

Further, in S2 of disposing the electrically-conductive paste, after the electrically-conductive paste 30 is disposed yet before the electrically-conductive paste 30 is sintered, it is preferable to perform drying of the electrically-conductive paste 30 and pressurizing of the dried electrically-conductive paste 30. The electrically-conductive paste 30 can be placed in an electric furnace and dried at a temperature higher than room temperature and lower than 100° C. Further, when the ceramic plate 1 including the electrically-conductive paste 30 is placed in the electric furnace, it is preferable that the electrically-conductive paste 30 is dried and pressurized simultaneously by using a pressurizing mold. By drying and pressurizing the electrically-conductive paste 30, volumetric shrinkage of the electrically-conductive paste 30 is less likely to occur in S3 of forming the electrically-conductive member.

### Electrically-Conductive Paste 30

The electrically-conductive paste 30 contains a metal having a melting point of 450° C. or more and 720° C. or less, and can further contain other components as necessary. Using the electrically-conductive paste 30 containing a metal having a melting point of 450° C. or more and 720° C. or less is preferable because the aluminum layer 4 can be suitably formed at the inner surface 3a defining the through hole 3, and the adhesion between the ceramic plate 1 and the electrically-conductive member 2 can be improved.

The electrically-conductive paste 30 has fluidity. Thus, the through hole 3 having any shape can be freely filled with the electrically-conductive paste 30, and the electrically-conductive paste 30 can be disposed by being cured after being applied in any desired shape and with any thickness.

### Metal Having Melting Point of 450° C. Or More and 720° C. Or Less

The metal having a melting point of 450° C. or more and 720° C. or less is not particularly limited. Examples the metal having a melting point of 450° C. or more and 720° C. or less include aluminum (Al) (melting point: about 660° C.), antimony (Sb) (melting point: about 630° C.), magnesium (Mg) (melting point: about 650° C.), and radium (Ra) (melting point: about 700° C.). One of these metals can be used alone or two or more of these metals can be used in combination.

The metal having a melting point of 450° C. or more and 720° C. or less can be an alloy. Examples of the alloy having a melting point of 450° C. or more and 720° C. or less include an Al—Cu-based alloy, an Al—Mn-based alloy, an Al—Si-based alloy, an Al—Mg-based alloy, an Al—Mg—Si-based alloy, and an Al—Zn—Mg-based alloy. Among them, the Al—Cu-based alloy is preferable.

The metal having a melting point of 450° C. or more and 720° C. or less is preferably metal particles. The median diameter of the metal particles is not particularly limited, and is preferably 0.1 μm or more and 10 μm or less, and more preferably 0.1 μm or more and 5 μm or less. As used herein, the median diameter is a 50% particle diameter (D50) in a volume distribution-based particle size distribution. Specifically, the median diameter refers to a particle diameter (volume median diameter) at which the volume cumulative frequency as measured by a laser diffraction/scattering particle size distribution measuring method reaches 50% from the small diameter side in a volume-based particle size distribution. The laser diffraction/scattering particle size distribution measuring method can be performed using, for example, a laser diffraction particle size distribution measuring apparatus (product name: MASTERSIZER 3000 manufactured by Malvern Instruments, Ltd.).

The shape of each of the metal particles is not particularly limited, and can be a spherical shape, a spheroidal shape, a flat shape, or any other shape. The flat shape is, for example, a shape having a thickness smaller than the maximum length in the plane direction.

The metal particles can be commercially available products or can be appropriately prepared by a publicly-known method.

### Other Components

Other components contained in the electrically-conductive paste 30 are not particularly limited, and examples of the other components include a solvent and a resin.

The content of at least one of the resin or the solvent is not particularly limited, and is preferably 0.2 mass % or more and 50 mass % or less, more preferably 0.2 mass % or more and 30 mass % or less, with respect to the total mass of the electrically-conductive paste 30.

The resin can be a commercially available product or can be appropriately prepared by a publicly-known method. Examples of the commercially available product of the resin include S-LEC (registered trademark) SV-26 manufactured by Sekisui Chemical Co., Ltd.

The content of the resin is not particularly limited, and is preferably 0.2 mass % or more and 30 mass % or less with respect to the total mass of the electrically-conductive paste 30. When the content of the resin is 0.2 mass % or more, the viscosity of the electrically-conductive paste 30 is increased, and thus the electrically-conductive paste 30 is easily disposed, and the adhesion between the electrically-conductive member 2 and the ceramic plate 1 is further improved. When the content of the resin is 30 mass % or less, the electrically-conductive paste 30 is more easily sintered.

The solvent is not particularly limited. The boiling point of the solvent is preferably 300° C. or less, more preferably 250° C. or less, and even more preferably 200° C. or less. By setting the boiling point of the solvent to 300° C. or less, the solvent is easily volatilized when the electrically-conductive paste 30 is heated and pressurized. The lower limit of the boiling point of the solvent is not particularly limited, and can be, for example, 80° C. or more.

The solvent can be a commercially available product or can be appropriately prepared by a publicly-known method. Examples of the commercially available product of the solvent include α-terpineol and butyl carbitol.

The content of the solvent is not particularly limited, and is preferably 2 mass % or more and 50 mass % or less with respect to the total mass of the electrically-conductive paste 30. When the content of the solvent is 2 mass % or more, the resin is easily dissolved. Further, when the content of the resin is 2 mass % or more, at which the resin is easily dissolved, the viscosity of the electrically-conductive paste 30 is increased, and the electrically-conductive member 2 is easily formed.

### (S3) Forming Electrically-Conductive Member

FIG. 6D is a schematic cross-sectional view illustrating an example of forming the electrically-conductive member in the method of manufacturing the ceramic substrate according to the first embodiment.

In S3 of forming the electrically-conductive member, the electrically-conductive member 2 is formed by sintering the electrically-conductive paste 30 at 450° C. or more and 720° C. or less. The melting point of aluminum is about 660° C. Therefore, when the aluminum layer 4 is sintered at 450° C. or more and 720° C. or less in S3 of forming the electrically-conductive member, at least a portion of the aluminum layer 4 is melted, and thus the adhesion between the aluminum layer 4 and the electrically-conductive member 2 is increased. That is, both aluminum in the electrically-conductive paste 30 and the aluminum layer 4 formed on the inner surface 3a defining the through hole 3 are melted at about 660° C., and thus the aluminum layer 4 and the electrically-conductive member 2 are mixed without an interface therebetween.

In S3 of forming the electrically-conductive member, the sintering can be performed by using, for example, a sintering furnace such as an electric furnace.

The sintering temperature when the electrically-conductive paste 30 is sintered is 450° C. or more and 720° C. or less, preferably 550° C. or more and 700° C. or less, and more preferably 600° C. or more and 695° C. or less. By setting the sintering temperature to 720° C. or less, a thermal load applied to the ceramic plate when the electrically-conductive paste 30 is sintered can be reduced, and thus the durability can be improved and a simple sintering furnace can be used to sinter the electrically-conductive paste 30. Further, keeping the sintering temperature low can reduce the possibility that the aluminum layer 4 formed on the inner surface 3a defining the through hole 3 diffuses into the electrically-conductive paste 30. By setting the sintering temperature to 450° C. or more, the adhesion between the ceramic plate 1 and the electrically-conductive member 2 formed within the through hole 3 can be improved.

The sintering atmosphere when the electrically-conductive paste 30 is sintered is not particularly limited, and is preferably an Ar atmosphere of 99.9% or more or a vacuum atmosphere of 10⁻⁵ Pa or less. This is because the aluminum layer 4 is easily oxidized.

The sintering time when the electrically-conductive paste 30 is sintered is not particularly limited, and is preferably 5 minutes or more and 60 minutes or less, more preferably 10 minutes or more and 50 minutes or less, and even more preferably 15 minutes or more and 45 minutes or less.

As described above, the ceramic substrate 100 including the ceramic plate 1 having the through hole 3, the continuous aluminum layer 4, and the electrically-conductive member 2 formed within the through hole 3 is obtained. The inner surface 3a defining the through hole 3 has irregularities, and the continuous aluminum layer 4 is disposed so as to enter the irregularities.

### (S4) Polishing or Grinding Electrically-Conductive Member

FIG. 6E is a schematic cross-sectional view illustrating an example of polishing or grinding the electrically-conductive member in the method of manufacturing the ceramic substrate according to the first embodiment.

In S4 of polishing or grinding the electrically-conductive member, the electrically-conductive member 2 is polished or ground such that at least one of the first surface 1a or the second surface 1b of the ceramic plate 1 in a portion covered by the electrically-conductive member 2 is exposed.

For example, in a case where only the through hole 3 of the ceramic plate 1 is filled with the electrically-conductive paste 30 in S2 of disposing the electrically-conductive paste, the ceramic substrate 100 obtained in S3 of forming the electrically-conductive member can be used as is. However, in a case where the electrically-conductive paste 30 is disposed so as to cover the openings of the through hole 3 and at least a portion of at least one of the first surface 1a or the second surface 1b of the ceramic plate 1, S4 of polishing or grinding the electrically-conductive member is further performed. As a result, the first surface 1a of the ceramic plate 1 and a surface (an exposed surface) of the electrically-conductive member 2 can be made substantially coplanar with each other, and the second surface 1b of the ceramic plate 1 and a surface (an exposed surface) of the electrically-conductive member 2 can be made substantially coplanar with each other.

In S3 of forming the electrically-conductive member, the first surface 1a and the second surface 1b of the ceramic plate 1 can be blackened in some cases; however, the blackened portion can be removed by performing S4 of polishing or grinding the electrically-conductive member.

### First Modification of First Embodiment

A first modification of the method of manufacturing the ceramic substrate according to the first embodiment differs from the method of manufacturing the ceramic substrate according to the first embodiment in that, in S1 of forming the through hole, the laser L is emitted such that the opening diameter of the through hole 3 in the first surface 1a of the ceramic plate 1 is larger than the opening diameter of the through hole 3 in the second surface 1b.

The shape of the through hole 3 in a cross-sectional view can be adjusted to a desired shape by changing the pulse width of the laser L, and further changing the output of the laser L as necessary. For example, as compared to the method of manufacturing the ceramic substrate according to the first embodiment, in the first modification, the output of the laser L can be reduced or the time for irradiation with the laser L can be shortened. The laser L is preferably emitted from the first surface 1a side of the ceramic plate 1.

### Second Embodiment

A method of manufacturing the ceramic substrate according to the second embodiment differs from the method of manufacturing the ceramic substrate according to the first embodiment in that S1A of forming the recess 5 in the ceramic plate 1 is performed instead of S1 of forming the through hole 3 in the ceramic plate 1. In the recess 5 formed in the ceramic plate 1, the opening diameter of the recess 5 in the first surface 1a of the ceramic plate 1 is substantially the same as the diameter of the bottom of the recess 5.

The recess 5 can be formed and the depth of the recess 5 can also be adjusted by changing the pulse width of the laser L, and further changing the output of the laser L as necessary. For example, as compared to the method of manufacturing the ceramic substrate according to the first embodiment, in the second embodiment, the output of the laser L can be reduced or the time for irradiation with the laser L can be shortened.

### First Modification of Second Embodiment

A first modification of the method of manufacturing the ceramic substrate according to the second embodiment differs from the method of manufacturing the ceramic substrate according to the second embodiment in that, in S1A of forming the recess 5 in the ceramic plate 1, the laser L is emitted such that the opening diameter of the recess 5 in the first surface 1a of the ceramic plate 1 is larger than the diameter of the bottom of the recess 5.

The shape of the recess 5 in a cross-sectional view can be adjusted to a desired shape by changing the pulse width of the laser L, and further changing the output of the laser L as necessary. For example, as compared to the method of manufacturing the ceramic substrate according to the second embodiment, in the first modification, the output of the laser L can be reduced or the time for irradiation with the laser L can be shortened.

### Second Modification of First Embodiment or Second Embodiment

A second modification of the method of manufacturing the ceramic substrate according to the first embodiment or the method of manufacturing the ceramic substrate according to the second embodiment differs from the method of manufacturing the ceramic substrate according to the first embodiment or the method of manufacturing the ceramic substrate according to the second embodiment, in that the electrically-conductive paste 30 further contains, in addition to an aluminum powder, at least one powder 31 selected from the group consisting of a powder of an alloy of aluminum and copper, a copper powder, a silver powder, and a ceramic powder.

The content of the at least one powder 31 selected from the group consisting of the powder of the alloy of aluminum and copper, the copper powder, the silver powder, and the ceramic powder in the electrically-conductive paste 30 is not particularly limited as long as the effects of the present disclosure are not impaired, and is preferably 20 mass % or more and 50 mass % or less when the total content of the aluminum powder and the powder 31 is taken as 100 mass %.

Each of the aluminum powder, the powder of the alloy of aluminum and copper, the copper powder, and the silver powder has high electrical conductivity. Further, because the melting point of the copper powder is 1,084° C., the copper powder is not easily melted in the electrically-conductive paste 30 when the electrically-conductive paste 30 is sintered in S3 of forming the electrically-conductive member, and the copper powder can be present in a state of being dispersed as powder in the electrically-conductive member 2. Accordingly, the electrical conductivity of the ceramic substrate 100 can be further improved.

Further, because the ceramic powder also has a high melting point, the ceramic powder is not easily melted in the electrically-conductive paste 30 when the electrically-conductive paste 30 is sintered in S3 of forming the electrically-conductive member, and the ceramic powder can be present in a state of being dispersed as powder in the electrically-conductive member 2. Accordingly, a difference between the linear expansion coefficient of the ceramic plate 1 and the linear expansion coefficient of the electrically-conductive member 2 can be reduced, and the reliability of the ceramic substrate 100 can be further improved.

### Third Modification of First Embodiment or Second Embodiment

A third modification of the method of manufacturing the ceramic substrate according to the first embodiment or the method of manufacturing the ceramic substrate according to the second embodiment differs from the method of manufacturing the ceramic substrate according to the first embodiment or the method of manufacturing the ceramic substrate according to the second embodiment, in that the third modification includes S1-1 of polishing or grinding the ceramic plate 1 after S1 of forming the through hole.

When aluminum is precipitated from the ceramic plate 1 in S1 of forming the through hole, burrs 12 can be generated around the opening of the through hole 3 in the first surface 1a of the ceramic plate 1 and the opening of the through hole 3 in the second surface 1b of the ceramic plate 1, or can be generated around the opening of the recess 5 of the ceramic plate 1.

In S1-1 of polishing or grinding the ceramic plate 1, it is preferable that the burrs 12 are removed by being polished or ground so as to make the periphery of the opening of the through hole 3 substantially coplanar with the first surface 1a and the periphery of the opening of the through hole 3 substantially coplanar with the second surface 1b, or make the periphery of the opening of the recess 5 substantially coplanar with the first surface 1a or the second surface 1b (a surface in which the recess 5 is formed).

In a case where the S1-1 of polishing or grinding the ceramic plate is not performed, burrs 12 can be removed simultaneously when the electrically-conductive member 2 is polished or ground in S4 of polishing or grinding the electrically-conductive member 2.

### Light-Emitting Device

A light-emitting device 200 according to an embodiment includes a ceramic substrate 100 according to an embodiment and a light-emitting element 202 disposed over the ceramic substrate 100 and including electrodes 205. The electrodes 205 are electrically connected to respective electrically-conductive members 2.

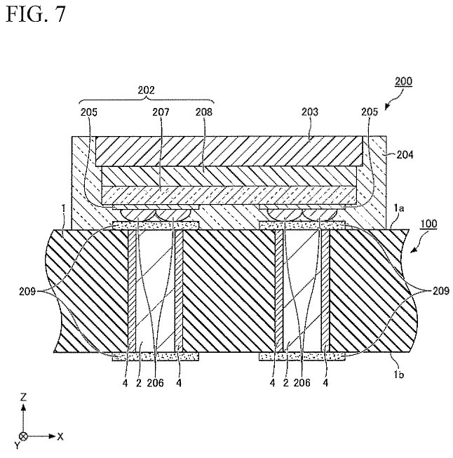

FIG. 7 is a schematic cross-sectional view illustrating an example of the light-emitting device 200 according to the embodiment. Each component of the light-emitting device 200 will be described below.

The light-emitting device 200 is a device including the light-emitting element 202 over the ceramic substrate 100 and configured to emit light. The number of light-emitting elements 202 can be one or more than one. In a case where the light-emitting device 200 includes a plurality of light-emitting elements 202, the arrangement of the light-emitting elements 202 is not particularly limited, and, for example, the plurality of light-emitting elements 202 can be arranged in a row.

In the light-emitting device 200, as an example, a light-transmissive member 203 covering a light extraction surface of the light-emitting element 202, a light-reflective member 204 covering lateral surfaces of the light-emitting element 202 and the first surface 1a of the ceramic plate 1 of the ceramic substrate 100, and metal bumps 206 electrically connecting the light-emitting element 202 to the electrically-conductive members 2 of the ceramic substrate 100 are disposed.

In the ceramic substrate 100, various patterns of wiring can be formed according to the application. In the light-emitting device 200 according to the embodiment, the light-emitting element 202 includes a pair of electrodes 205 on the same surface, and is mounted face-down with the surface provided with the electrodes 205 facing the first surface 1a of the ceramic plate 1 of the ceramic substrate 100.

The light-emitting device 200 according to the embodiment can be mounted face-up by placing the pair of electrodes 205 of the light-emitting element 202 on the side of the light-emitting device 200 opposite to the side in contact with the ceramic substrate 100, and connecting the pair of electrodes 205 to the electrically-conductive member 2 of the ceramic substrate 100 by wires.

### Light-Emitting Element 202

The light-emitting element 202 includes the pair of electrodes 205, a semiconductor layered body 207, and an element substrate 208.

For example, the light-emitting element 202 includes the semiconductor layered body 207 on the bottom surface of the element substrate 208, and includes the pair of electrodes 205 on the semiconductor layered body 207.

The semiconductor layered body 207 can use any composition according to a desired emission wavelength, and can use, for example, a nitride semiconductor (InₓAl_{y}Ga_{1-x-y}N, 0≤X, 0≤Y, X+Y≤1) or GaP, which can emit blue light or green light, or GaAlAs or AlInGaP, which can emit red light. One of these can be used alone or two or more of these can be used in combination. The size and the shape of the light-emitting element 202 can be appropriately selected according to the purpose of use.

As an example, a sapphire substrate or a silicon substrate is used as the element substrate 208.

The electrodes 205 are connected to the electrically-conductive members 2 of the ceramic substrate 100 by the metal bumps 206 via bonding members 209. One of the electrodes 205 is a p-electrode and the other is an n-electrode, and the p-electrode is disposed at a distance from the n-electrode so as not to be electrically short-circuited therewith. As an example, the electrodes 205 are configured such that one p-electrode and one n-electrode are disposed at respective positions; however, one of the p-electrode and the n-electrode can be disposed at two positions and the other can be disposed at one position.

### Light-Transmissive Member 203

The light-transmissive member 203 is disposed on a flat surface, serving as a light extraction surface, of the element substrate 208. For example, the light-transmissive member 203 is formed of a light-transmissive resin material, and can use an epoxy resin, a silicone resin, or a resin in which an epoxy resin and a silicone resin are mixed. The light-transmissive member 203 can include a phosphor. For example, when the light-transmissive member 203 includes a phosphor that absorbs blue light from the light-emitting element 202 and emits yellow light, white light can be emitted from the light-emitting element 202. Further, the light-transmissive member 203 can include a plurality of types of phosphors. For example, when the light-transmissive member 203 includes a phosphor that absorbs blue light from the semiconductor layered body 207 and emits green light and a phosphor that emits red light, white light can be emitted from the light-emitting element 202.

Examples of such a phosphor include yttrium aluminum garnet based phosphors (for example, Y₃(Al,Ga)₅O₁₂:Ce,), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), nitride based phosphors such as β-SiAlON based phosphors (for example, (Si,Al)₃(O,N)₄:Eu), α-SiAlON phosphors (for example, Mz(Si,Al)₁₂(O,N)₁₆ (where 0<z≤2, and M is Li, Mg, Ca, Y, or a lanthanide element excluding La and Ce)), CASN-based phosphors (for example, CaAlSiN₃:Eu,), and SCASN-based phosphors (for example, (Sr,Ca)AlSiN₃:Eu), fluoride based phosphors such as KSF based phosphors (for example, K₂SiF₆:Mn), KSAF based phosphors (for example, K₂(Si,Al)F₆:Mn), and MGF based phosphors (for example, 3.5MgO·0.5MgF₂·GeO₂:Mn), quantum dot phosphors such as perovskite and chalcopyrite, and the like.

### Metal Bumps 206

The metal bumps 206 are members that electrically connect the electrodes 205 to the electrically-conductive members 2. The metal bumps 206 can be disposed either on the electrode 205 side or on the electrically-conductive member 2 side. The shape, the size, and the number of the metal bumps 206 can be appropriately set as long as metal bumps 206 can be disposed within the range of a corresponding electrode 205. The size of the metal bumps 206 can be appropriately adjusted according to the size of the semiconductor layered body 207, the required light emission output of the light-emitting element, and the like. For example, each of the metal bumps 206 can have a diameter of about several tens of m to several hundreds of m.

The metal bumps 206 can be formed of, for example, gold (Au), silver (Ag), copper (Cu), aluminum (Al), tin (Sn), platinum (Pt), zinc (Zn), nickel (Ni), or an alloy thereof. The metal bumps 206 can be formed of, for example, stud bumps publicly-known in the art. The stud bumps can be formed by a stud bump bonder, a wire bonding apparatus, or the like. Further, the metal bumps 206 can be formed by a method publicly-known in the art such as electroplating, electroless plating, vapor deposition, or sputtering.

As an example, the metal bumps 206 are bonded via the bonding members 209. Examples of the bonding members 209 used in the present embodiment include solders such as tin-bismuth based solders, tin-copper based solders, tin-silver based solders, and gold-tin based solders, eutectic alloys such as alloys containing Au and Sn as main components, alloys containing Au and Si as main components, and alloys containing Au and Ge as main components, paste materials of silver, gold, palladium, and the like, anisotropic conductive materials such as anisotropic conductive paste (ACP) and anisotropic conductive film (ACF), brazing materials formed of low melting point metals, and conductive adhesives and conductive composite adhesives of a combination of any of these.

### Light-Reflective Member 204

The light-reflective member 204 is a member having light reflectivity. The light-reflective member 204 covers the first surface 1a of the ceramic plate 1 of the ceramic substrate 100 and covers the lateral surfaces of the light-emitting element 202. Further, the light-reflective member 204 exposes the light extraction surface of the light-emitting element 202 and is coplanar with the light-transmissive member 203. As an example, the light-reflective member 204 is also disposed between the lower surface of the light-emitting element 202 and the first surface 1a of the ceramic plate 1 of the ceramic substrate 100.

The light-reflective member 204 preferably has a high reflectance in order to effectively use light from the light-emitting element 202. The color of the light-reflective member 204 is preferably white. For example, the reflectance of the light-reflective member 204 is preferably 90% or more, and more preferably 94% or more at the wavelength of the light emitted from the light-emitting element 202.

Examples of a resin used for the light-reflective member 204 include thermoplastic resins such as an acrylic resin, a polycarbonate resin, a cyclic polyolefin resin, a polyethylene terephthalate resin, a polyethylene naphthalate resin, and a polyester resin, and thermosetting resins such as an epoxy resin and a silicone resin. Further, as a light-diffusing material, for example, a publicly-known material such as titanium oxide, silicon oxide, aluminum oxide, zinc oxide, or glass, can be used.

In the light-emitting device 200, one light-emitting element 202 is used as one unit to control brightness and turning on/off. However, the number of light-emitting elements 202 included in one unit can be one or more than one. For example, four light-emitting elements 202 arranged in one row and four columns or in two rows and two columns, or nine light-emitting elements 202 arranged in three rows and three columns can be used as one unit, and the number of light-emitting elements 202 is not limited.

### Application Example of Light-Emitting Devices

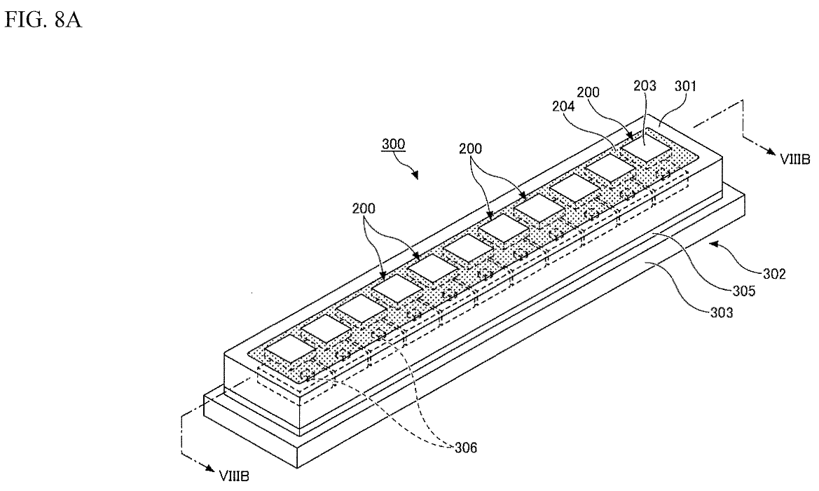

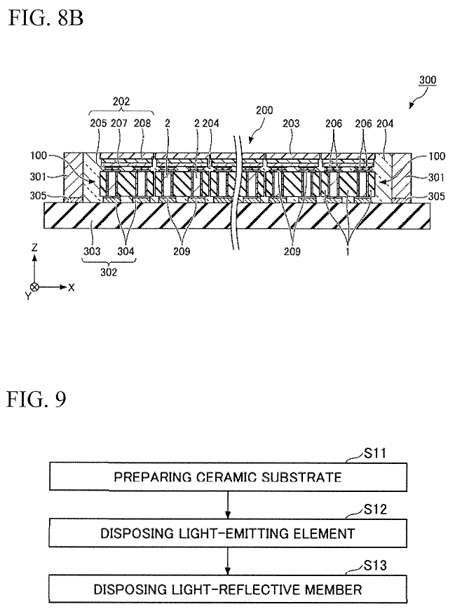

FIG. 8A is a perspective view illustrating an application example of light-emitting devices according to an embodiment. FIG. 8B is a cross-sectional view illustrating a cross section taken along line VIIIB-VIIIB of FIG. 8A. In FIG. 8B, some configurations of FIG. 8A are not depicted.

A light-emitting module 300 including a plurality of (eleven in FIG. 8A) light-emitting devices 200 arranged in a row can be used, and the eleven light-emitting devices 200 can be mounted on one ceramic substrate 100. A configuration of the light-emitting module 300 will be described below.

The light-emitting module 300 includes the eleven light-emitting devices 200 arranged in a row, a light-reflective member 204 surrounding each of the outer peripheries of the light-emitting devices 200, and a frame 301 located outward of the light-reflective member 204. A module substrate 302 is connected to a surface opposite to a first surface 1a of a ceramic plate 1 of a ceramic substrate 100.

The frame 301 is a member for surrounding the light-reflective member 204 that covers the plurality of light-emitting devices 200. The frame 301 is formed in a rectangular ring-like shape, that is, for example, a rectangular shape in a plan view, and is disposed to surround the light-reflective member 204.

The frame 301 can be formed by using a member having a frame shape and formed of a metal, an alloy, or a ceramic. Examples of the metal include iron (Fe), copper (Cu), nickel (Ni), aluminum (Al), silver (Ag), gold (Au), platinum (Pt), titanium (Ti), tungsten (W), and palladium (Pd). Examples of the alloy include an alloy containing at least one selected from the group consisting of Fe, Cu, Ni, Al, Ag, Au, Al, Pt, Ti, W, and Pd.

A resin material can be used as the frame 301. In this case, a metal, an alloy, or a ceramic member as described above can be embedded in the frame 301 formed of the resin material. Alternatively, a part of the frame 301 can be formed of the resin material and the other part of the frame 301 can be formed of the metal, the alloy, or the ceramic member.

The module substrate 302 is a member on which the light-emitting devices 200 are mounted, and electrically connects the light-emitting devices 200 to the outside. The module substrate 302 is formed in, for example, a substantially rectangular shape in a plan view. The module substrate 302 includes a substrate part 303 and wiring parts 304.

As a material of the substrate part 303, for example, an insulating material is preferably used, and a material that does not easily transmit light emitted from light-emitting elements 202, external light, and the like is preferably used. Examples of the material of the substrate part 303 that can be used include ceramics such as aluminum oxide, aluminum nitride, and mullite; thermoplastic resins such as polyamide, polyphthalamide, polyphenylene sulfide, and liquid crystal polymer; and thermosetting resins such as an epoxy resin, a silicone resin, a modified epoxy resin, a urethane resin, and a phenol resin. Among them, as the material of the substrate part 303, a ceramic having good heat dissipation is preferably used.

Further, the wiring parts 304 are formed on the substrate part 303 at respective positions facing electrically-conductive members 2, and are located on the side of the ceramic plate 1 of the ceramic substrate 100 opposite to the first surface 1a side on which the light-emitting devices 200 are arranged. Examples of a material of the wiring parts 304 include those exemplified as the material used for the electrically-conductive members 2.

The module substrate 302 is bonded to the frame 301 via an electrically-conductive adhesive 305, and is disposed such that the electrically-conductive members 2 and the wiring parts 304 are bonded together. As the electrically-conductive adhesive 305, for example, eutectic solder, an electrically-conductive paste, a bump, or the like can be used. In the light-emitting devices 200, protective elements 306 are disposed on the ceramic substrate 100 in parallel with the light-emitting elements 202.

The light-emitting module 300 is configured as described above. Thus, the light-emitting module 300 is driven as follows. That is, in the light-emitting module 300, a current is supplied from an external power source to the light-emitting elements 202 via the wiring parts 304, the electrically-conductive members 2, and electrodes 205, and so the light-emitting elements 202 emit light. Of the light emitted from the light-emitting elements 202, light traveling upward is extracted to the outside above the light-emitting devices 200 via light-transmissive members 203. Further, light traveling downward is reflected by the ceramic substrate 100 and is extracted to the outside of the light-emitting devices 200 via light-transmissive members 203. Further, light traveling between a light-emitting element 202 and the frame 301 is reflected by the light-reflective member 204 and the frame 301 and is extracted to the outside of the light-emitting devices 200 via a light-transmissive member 203. Further, light traveling between light-emitting elements 202 is reflected by the light-reflective member 204 and is extracted to the outside of the light-emitting devices 200 via light-transmissive members 203. At this time, by setting a space between light-transmissive members 203 to be narrow (to 0.2 mm or less, for example), when the light-emitting module 300 is used as a light source of a vehicle headlight, for example, a configuration of an optical system can be simplified and reduced in size.

When the light-emitting module 300 is manufactured, the light-emitting devices 200 are arranged on a sheet member and the frame 301 is disposed around the light-emitting devices 200, and in this state, a space surrounded by the frame 301 and the sheet member is filled with the light-reflective member 204 such that the light-reflective member 204 is disposed. Subsequently, the light-emitting devices 200 supported by the frame 301 and the light-reflective member 204 are disposed on the module substrate 302 on which the wiring parts 304 304 and the electrically-conductive adhesive 305 are disposed, and the electrically-conductive members 2 are electrically connected to the wiring parts 304. In this manner, the light-emitting module 300 is manufactured.

### Method of Manufacturing Light-Emitting Device

A method of manufacturing a light-emitting device according to an embodiment includes preparing a ceramic substrate 100 manufactured by a method of manufacturing a ceramic substrate 100 according to an embodiment, and disposing a light-emitting element 202 including electrodes 205 over the ceramic substrate 100. The electrodes 205 are electrically connected to respective electrically-conductive members 2.

FIG. 9 is a flowchart illustrating an example of the method of manufacturing the light-emitting device according to the embodiment. As an example, the method of manufacturing the light-emitting device according to the embodiment includes disposing a light-reflective member.

### (S11) Preparing Ceramic Substrate

In S11 of preparing the ceramic substrate 100, the ceramic substrate 100 according to the embodiment is prepared.

The ceramic substrate 100 can include a plurality of regions where light-emitting elements 202 are to be disposed and can have a size for singulation to separate light-emitting devices 200 after a light-reflective member 204 is disposed, or the ceramic substrate 100 can have a size for each light-emitting device 200.

### (S12) Disposing Light-Emitting Element

In S12 of disposing the light-emitting element, the light-emitting element 202 including the electrodes 205 is disposed over the ceramic substrate 100. In S12 of disposing the light-emitting element, metal bumps 206 are used to connect the electrodes 205 of the light-emitting element 202 to bonding members 209 disposed on electrically-conductive member 2. A light-transmissive member 203 is connected to an element substrate 208 in advance, and in this state, the light-emitting element 202 is disposed over the ceramic substrate 100. A light-transmissive bonding material is used to bond the light-transmissive member 203 to the element substrate 208.

### (S13) Disposing Light-Reflective Member

In S13 of disposing the light-reflective member, the light-reflective member 204 is disposed so as to cover a first surface 1a of a ceramic plate 1 of the ceramic substrate 100 and lateral surfaces of the light-emitting element 202. The light-reflective member 204 is disposed on the ceramic substrate 100 so as to surround the light-emitting element 202 and expose the upper surface of the light-transmissive member 203, which serves as a light extraction surface of the light-emitting element 202. The light-reflective member 204 is disposed so as to have a rectangular shape in a plan view.

In the method of manufacturing the light-emitting device according to the embodiment, singulation work is performed as necessary after S13 of disposing the light-reflective member. One unit of the light-emitting device 200 is set in advance by the number of light-emitting elements 202 to be used. Therefore, when a plurality of the light-emitting devices 200 are manufactured at a time, the singulation work is performed. When the singulation work is performed, the plurality of light-emitting devices 200 are manufactured by being cut in a grid pattern. Examples of the cutting method include methods using a rotating blade having a disc shape, an ultrasonic cutter, and a laser light irradiation blade.

### EXAMPLES

The present invention is specifically described below through Examples; however, the present invention is not limited to these Examples.

### Example 1

An electrically-conductive paste 30 was prepared by mixing 90 parts by mass of an aluminum powder, 1 part by mass of polyvinyl acetal, and 9 parts by mass of α-terpineol.

By using the electrically-conductive paste 30, a ceramic substrate 100 was manufactured by the method for manufacturing the ceramic substrate according to the first embodiment based on the flowchart illustrated in FIG. 5. In S1 of forming the through hole, a fiber laser (CW: 1 nanosecond, wavelength: 532 nm, and output: 1,500 W) was used. In S3 of forming the electrically-conductive member, a ceramic plate 1 in which the electrically-conductive paste 30 is disposed in a through hole 3 was sintered at 660° C. for 30 minutes.

### Examples 2 to 4

In Examples 2 to 4, ceramic substrates 100 were manufactured by the same method as that in Example 1, except that the composition of the electrically-conductive paste 30 was changed to compositions indicated in Table 1.

### Example 5

In Example 5, a ceramic substrate 100 was manufactured by the same method as that in Example 1, except that a through hole 3 was formed by using a UV laser instead of the fiber laser in S1 of forming the through hole.

### Comparative Examples 1 and 2

In Comparative Examples 1 and 2, ceramic substrates were manufactured in the same method as in Example 1, except that the sintering temperature in S3 of forming the electrically-conductive member was changed to sintering temperatures illustrated in Table 1.

TABLE 1

| | | | | | | | COM- | COM- |
|---|---|---|---|---|---|---|---|---|
| | | | | | | | PARATIVE | PARATIVE |
| | | EXAM- | EXAM- | EXAM- | EXAM- | EXAM- | EXAMPLE | \|EXAMPLE |
| | | PLE 1 | PLE 2 | PLE 3 | PLE 4 | PLE 5 | 1 | 2 |
| COMPOSITION | ALUMINUM | 90 | 60 | 50 | 80 | 90 | 90 | 90 |
| OF | POWDER | | | | | | | |
| ELECTRICALLY- | COPPER | — | 30 | — | — | — | — | — |
| CONDUCTIVE | POWDER | | | | | | | |
| PASTE | POWDER OF | — | — | 40 | — | — | — | — |
| [PARTS BY | ALLOY OF | | | | | | | |
| MASS] | ALUMINUM | | | | | | | |
| | AND COPPER | | | | | | | |
| | CERAMIC | — | — | — | 10 | — | — | — |
| | POWDER | | | | | | | |
| | POLYVINYL | 1 | 1 | 1 | 1 | 1 | 1 | 1 |
| | ACETAL | | | | | | | |
| | α-TERPINEOL | 9 | 9 | 9 | 9 | 9 | 9 | 9 |

| | | | | | | | |
|---|---|---|---|---|---|---|---|
| FORMATION | FIBER | FIBER | FIBER | FIBER | UV | FIBER | FIBER |
| METHOD OF | LASER | LASER | LASER | LASER | LASER | LASER | LASER |
| THROUGH HOLE | | | | | | | |
| SINTERING | 660 | 660 | 660 | 660 | 660 | 400 | 730 |
| TEMPERATURE [° C.] | | | | | | | |

After S1 of forming a through hole in each of the ceramic substrates according to Examples 1 to 5 and Comparative Examples 1 and 2 was performed, ceramic plates 1 were cut in the thickness direction by laser irradiation and were observed with a metallurgical microscope at a magnification of 250 times. In Examples 1 to 5 and Comparative Examples 1 and 2, aluminum layers 4 precipitated on the inner surfaces 3a defining through holes 3 were observed.

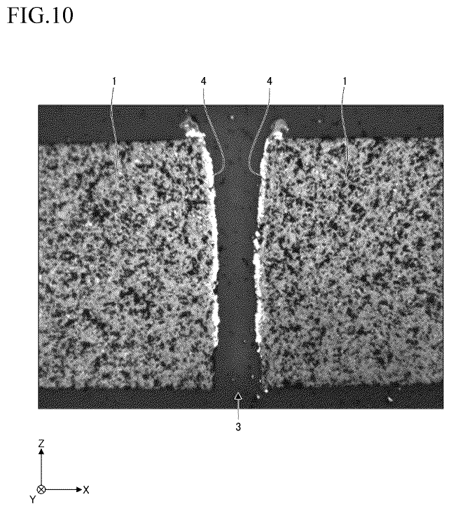

As an example, FIG. 10 illustrates a cross-sectional observation image of the through hole 3 after irradiation with the laser L in S1 of forming the through hole in Example 1. From the observation image, the aluminum layer 4 present on the inner surface 3a defining the through hole 3 and within the inner surface 3a was confirmed. The average thickness of the aluminum layer 4 was 20 μm, and the opening diameter of the through hole 3 was 100 μm.

The average thicknesses of the aluminum layers 4 and the opening diameters of the through holes 3 in Examples 2 to 4 were also approximately the same as those in Example 1.

In Example 5, irregularities were formed on the inner surface 3a defining the through hole 3, and the precipitated aluminum layer 4 was observed. However, because the UV laser was not intended for thermal processing, the average thickness of the aluminum layer 4 was 5 m or less.

In Comparative Example 1, an interface between the inner surface 3a defining the through hole 3 and an electrically-conductive member 2 was confirmed, and sufficient adhesion was not obtained. It is considered that this is because the sintering temperature was less than 450° C., and thus a portion of aluminum nitride in the vicinity of the inner surface 3a defining the through hole 3 of the ceramic plate 1 was not sufficiently melted and sublimated.

In Comparative Example 2, the durability of the ceramic substrate was not sufficient. It is considered that this is because the sintering temperature exceeded 720° C., and thus a thermal load was applied to the ceramic plate 1. From the viewpoint of high output and high integration of electronic devices such as light-emitting devices, further thermal stress and a thermal load are repeatedly applied when a ceramic substrate is used. Therefore, the durability of the ceramic substrate is important.

As described above, the present invention has been described based on specific embodiments; however, the above-described embodiments are merely examples, and the present invention is not limited by the above-described embodiments. The above-described embodiments can be embodied in various other forms, and various combinations, omissions, substitutions, additions, modifications, and the like can be made without departing from the spirit of the invention. These embodiments and variations thereof are included in the scope and spirit of the invention and are within the scope of the invention described in the claims and equivalents thereof.

According to one embodiment of the present disclosure, a method of manufacturing a ceramic substrate and a method of manufacturing a light-emitting device, in which high durability and good heat dissipation are obtained and the adhesion between a ceramic plate and an electrically-conductive member within a through hole or a recess of the ceramic plate can be improved, can be provided.

1. A method of manufacturing a ceramic substrate, the method comprising:
forming a through hole or a recess in a ceramic plate containing aluminum nitride by irradiating the ceramic plate with a laser such that aluminum is precipitated, the ceramic plate having a first surface and a second surface opposite to the first surface;
disposing an electrically-conductive paste within the through hole or the recess; and
forming an electrically-conductive member by sintering the electrically-conductive paste at a temperature in a range of 450° C. or more and 720° C. or less.

2. The method of manufacturing the ceramic substrate according to claim 1, wherein, in the disposing of the electrically-conductive paste, the electrically-conductive paste is an electrically-conductive paste containing a metal having a melting point of 450° C. or more and 720° C. or less.

3. The method of manufacturing the ceramic substrate according to claim 1, wherein, in the disposing of the electrically-conductive paste, the electrically-conductive paste is disposed so as to cover:
an opening of the through hole or the recess, and
at least a portion of at least one of the first surface or the second surface of the ceramic plate.

4. The method of manufacturing the ceramic substrate according to claim 3, wherein the forming of the electrically-conductive member includes polishing or grinding the electrically-conductive member such that the at least one of the first surface or the second surface of the ceramic plate is exposed.

5. The method of manufacturing the ceramic substrate according to claim 1, wherein the electrically-conductive paste contains an aluminum powder.

6. The method of manufacturing the ceramic substrate according to claim 5, wherein the electrically-conductive paste further contains at least one material selected from a group consisting of a powder of an alloy of aluminum and copper, a copper powder, a silver powder, and a ceramic powder.

7. The method of manufacturing the ceramic substrate according to claim 5, wherein the electrically-conductive paste further contains a powder of an alloy of aluminum and copper.

8. The method of manufacturing the ceramic substrate according to claim 5, wherein the electrically-conductive paste further contains a copper powder.

9. The method of manufacturing the ceramic substrate according to claim 5, wherein the electrically-conductive paste further contains a silver powder.

10. The method of manufacturing the ceramic substrate according to claim 5, wherein the electrically-conductive paste further contains a ceramic powder.

11. The method of manufacturing the ceramic substrate according to claim 1, wherein, in the forming of the through hole or the recess, in a case where the through hole is formed, an opening diameter of the through hole in the first surface of the ceramic plate is larger than an opening diameter of the through hole in the second surface of the ceramic plate.

12. The method of manufacturing the ceramic substrate according to claim 1, wherein, in the disposing of the electrically-conductive paste, the electrically-conductive paste is disposed such that the electrically-conductive paste contacts an inner surface defining the through hole or the recess.

13. The method of manufacturing the ceramic substrate according to claim 1, wherein, in the forming of the through hole or the recess, the ceramic plate is thermally processed by being irradiated with the laser such that the aluminum is precipitated on an inner surface of the through hole or the recess.

14. The method of manufacturing the ceramic substrate according to claim 13, wherein the laser has an oscillation wavelength of 750 nm or more.

15. The method of manufacturing the ceramic substrate according to claim 14, wherein the laser has an output of 500 W or more.

16. The method of manufacturing the ceramic substrate according to claim 13, wherein the laser has an output of 500 W or more.

17. The method of manufacturing the ceramic substrate according to claim 1, wherein, in the forming of the through hole or the recess, the ceramic plate is a sintered ceramic plate.

18. The method of manufacturing the ceramic substrate according to claim 1, wherein:
in the forming of the through hole or the recess, the through hole is formed in the ceramic plate; and
in the disposing of the electrically conductive paste, the electrically-conductive paste is disposed within the through hole.

19. The method of manufacturing the ceramic substrate according to claim 1, wherein:
in the forming of the through hole or the recess, the recess is formed in the ceramic plate; and
in the disposing of the electrically conductive paste, the electrically-conductive paste is disposed within the recess.

20. A method of manufacturing a light-emitting device, the method comprising:
preparing the ceramic substrate manufactured by the method of claim 1; and
disposing a light-emitting element including an electrode over the ceramic substrate, wherein
the electrode and the electrically-conductive member are electrically connected to each other.
